(19) United States
(12) Patent Application Publication
(10) Pub. No.: US 2020/0199358 A1
(43) Pub. Date: Jun. 25, 2020

(54) HYBRID COPOLYMER COMPOSITION FOR PROTECTING FOLDABLE DISPLAYS

(71) Applicant: Tactus Technology, Inc., Fremont, CA (US)

(72) Inventors: Curtis Takagi, Fremont, CA (US); Matthew Han, Fremont, CA (US); Justin Virgili, Fremont, CA (US); Ryosuke Isobe, Fremont, CA (US); Brian Flamm, Fremont, CA (US)

(21) Appl. No.: 16/723,797

(22) Filed: Dec. 20, 2019

Related U.S. Application Data
(60) Provisional application No. 62/806,808, filed on Feb. 16, 2019.
(60) Provisional application No. 62/783,067, filed on Dec. 20, 2018.

(51) Int. Cl. C08L 75/04; C08G 18/73; C08G 18/80; C08G 18/32; C08L 75/02; H01L 51/52; C08G 18/24; C08G 18/42; C08K 5/18

(52) U.S. Cl. CPC C08L 75/04; C08G 18/73; C08G 18/8025; C08G 18/3221; C08K 5/18; H01L 51/5253; C08G 18/246; C08G 18/4277; C08L 75/02

(57) ABSTRACT

A hybrid copolymer composition includes: a first proportion of an aliphatic-diisocyanate terminated polyol; a second proportion of an aromatic diisocyanate; a third proportion of an aromatic diamine curative configured to extend a chain length of the aliphatic-diisocyanate-terminated polyol and the aromatic diisocyanate; a fourth proportion of a polyester polyol configured to polymerize with the aliphatic-diisocyanate-terminated polyol; and a fifth proportion of a high functionality dendrimer configured to crosslink polymer chains of the aliphatic-diisocyanate-terminated polyol. Further, the hybrid copolymer can be configured to form a protective film layer in a foldable electronic display, the foldable electronic display including: a cover layer arranged over the protective film layer; and an array of organic light-emitting diodes arranged beneath the protective film layer.

### CROSS-REFERENCE TO RELATED APPLICATIONS

This Application claims the benefit of U.S. Provisional Application No. 62/806,808, filed on 16 Feb. 2019, and U.S. Provisional Application No. 62/783,067, filed on 20 Dec. 2018, each of which are incorporated in their entireties by this reference.

This application is related to U.S. patent application Ser. No. 15/895,971, filed on 29 Apr. 2018, which is incorporated in its entirety by this reference.

### TECHNICAL FIELD

This invention relates generally to the field of hybrid copolymer chemistry and more specifically to a new and useful composition for protecting digital displays in the field of hybrid copolymer chemistry.

### BRIEF DESCRIPTION OF THE FIGS.

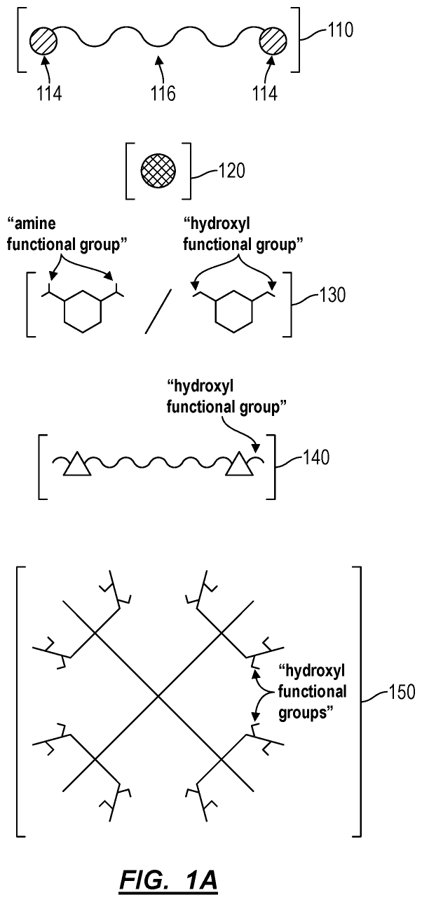

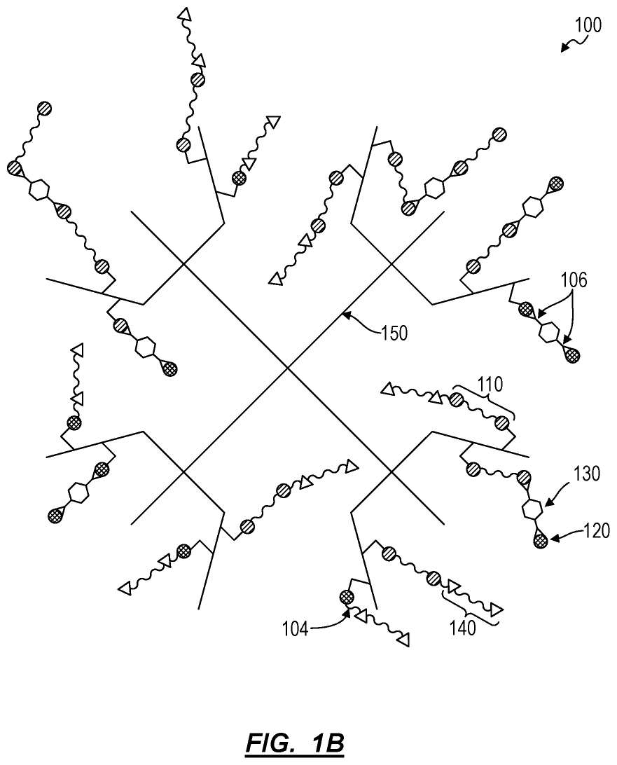

FIGS. 1A and 1B are a schematic representation of a composition;

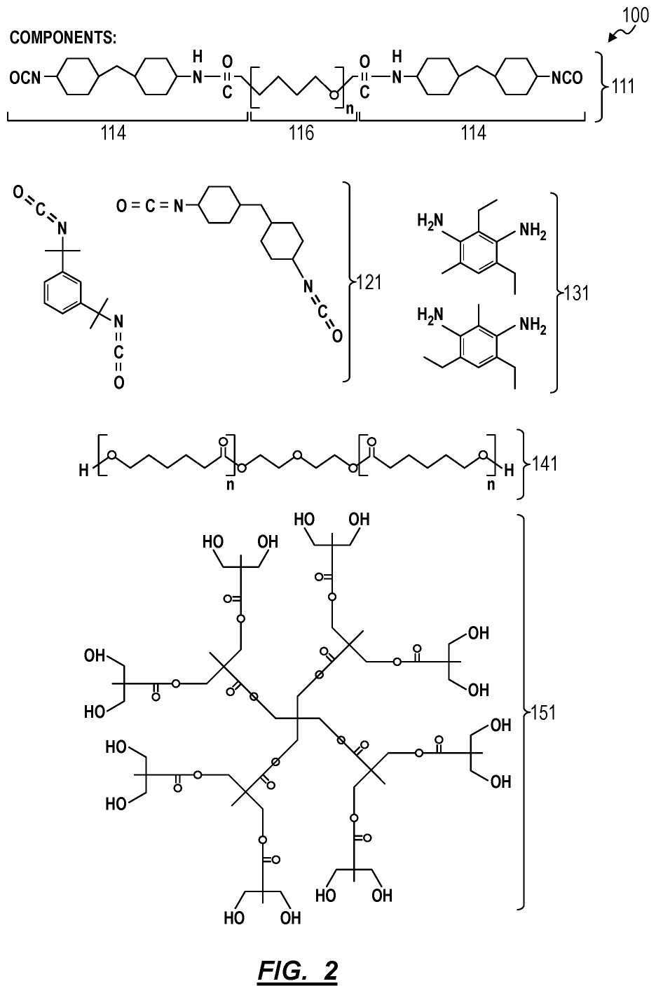

FIG. 2 is a schematic representation of the composition;

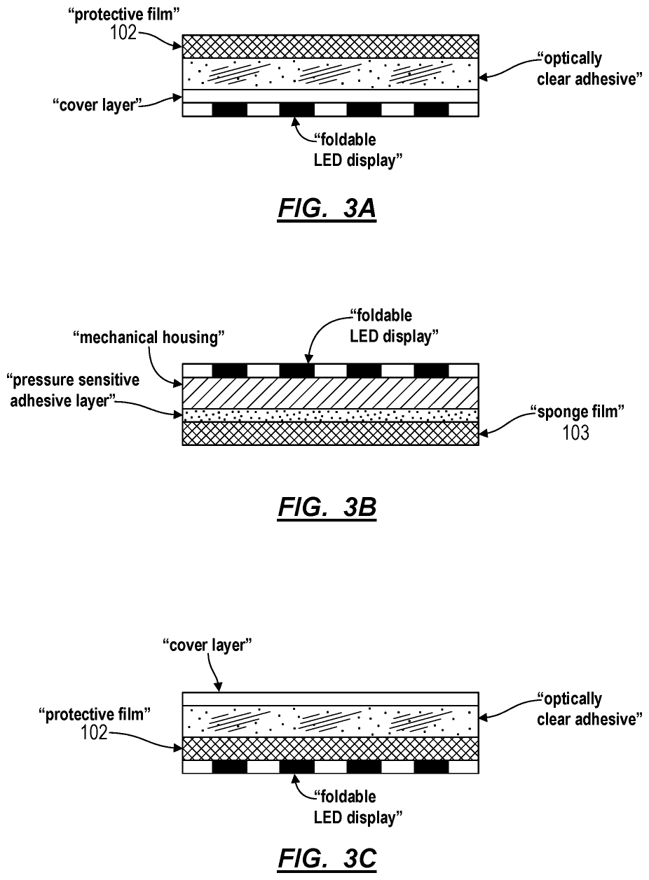

FIGS. 3A, 3B, and 3C are schematic representations of a foldable light-emitting diode display; and

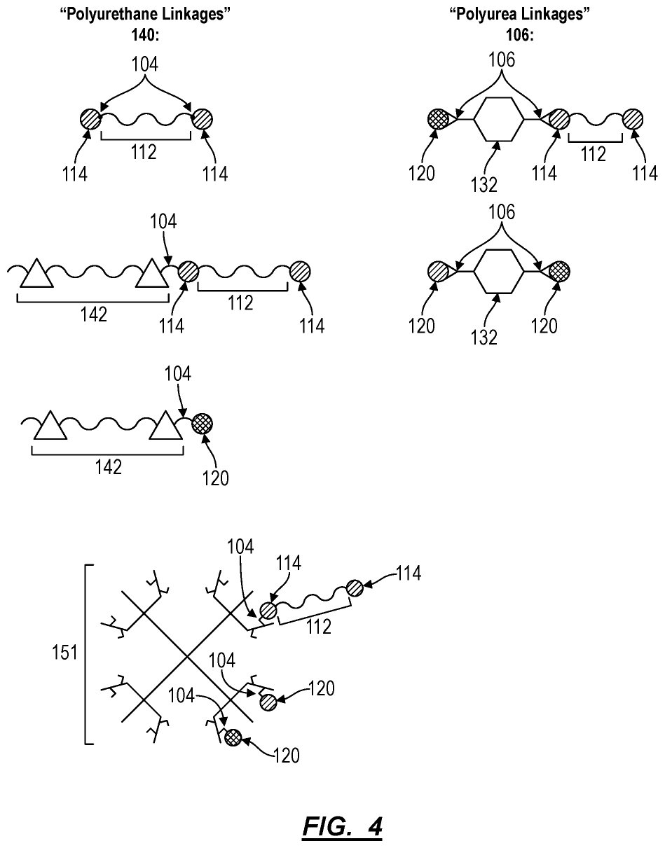

FIG. 4 is a schematic representation of components of the composition.

### DESCRIPTION OF THE EMBODIMENTS

The following description of embodiments of the invention is not intended to limit the invention to these embodiments but rather to enable a person skilled in the art to make and use this invention. Variations, configurations, implementations, example implementations, and examples described herein are optional and are not exclusive to the variations, configurations, implementations, example implementations, and examples they describe. The invention described herein can include any and all permutations of these variations, configurations, implementations, example implementations, and examples.

### 1. Composition

As shown in FIGS. 1A and 1B, a hybrid copolymer composition 100 for protecting electronic displays includes: a first proportion of a polyisocyanate-terminated polyol 110; a second proportion of an additional polyisocyanate 120; a third proportion of a curative 130 configured to extend a chain length of the polyisocyanate-terminated polyol 110 and the additional polyisocyanate 120; a fourth proportion of a soft polymer chain 140 configured to polymerize with the polyisocyanate-terminated polyol 110 and the additional polyisocyanates 120; and a fifth proportion of a high functionality crosslinker 150 configured to crosslink the polyisocyanate-terminated polyol 110 and the additional polyisocyanate.

As shown in FIG. 2, one variation of the hybrid copolymer composition 100 includes: a first proportion of an aliphatic-diisocyanate-terminated polyol 111; a second proportion of an additional diisocyanate 121; a third proportion of an aromatic diamine curative 131 configured to extend a chain length of the aliphatic-diisocyanate-terminated polyol 111 and the additional diisocyanate 121; a fourth proportion of a polyester polyol 141 configured to polymerize with the first proportion of aliphatic-diisocyanate-terminated polyol 111 and second proportion of additional diisocyanate 121; and a fifth proportion of a high functionality dendrimer 151 configured to crosslink polymer chains of the aliphatic-diisocyanate-terminated polyol.

One variation of the hybrid copolymer composition 100 includes a molar ratio of a first number of polyurethane linkages 104 to a second number of polyurea linkages 106 between two-to-five and six-to-five. In this variation, the first number of polyurethane linkages 104: connect a first quantity of polyether polyol segments 112 to a second quantity of aliphatic diisocyanate terminations 114; connect a third quantity of polyester polyol segments 142 to the second quantity of the aliphatic diisocyanate terminations 114 and a fourth quantity of additional diisocyanates 120; and connect a fifth quantity of a high functionality crosslinker 150 to the second quantity of the aliphatic diisocyanate terminations 114 and the fourth quantity of additional diisocyanates 120. In this variation, the second number of polyurea linkages 106 connect a sixth quantity of an aromatic polyamine curative 132 to the second quantity of the aliphatic diisocyanate terminations 114 and the fourth quantity of additional diisocyanates 120.

In one variation, the hybrid copolymer composition 100 includes: a first proportion of a polyisocyanate-terminated polyol; a second proportion of an additional polyisocyanate; a third proportion of a curative; a fourth proportion of a soft polymer chain configured to interrupt crystallization of the first quantity of the polyisocyanate-terminated polyol below 50 degrees Celsius; and a high functionality crosslinker. In this variation, the hybrid copolymer composition exhibits: a first storage modulus between 400 MPa and 1400 MPa at −20 degrees Celsius; a second storage modulus between 10 MPa and 100 MPa at 85 degrees Celsius; a room temperature storage modulus between 100 MPa and 400 MPa at 20 degrees Celsius; and an elongation at break greater than 400%.

### 2. Applications

Generally, as shown in FIGS. 1A and 1B, a hybrid copolymer composition 100 includes a polyisocyanate-terminated polyol 110, additional polyisocyanates 120; a curative 130/chain length extender, a soft polymer chain 140, and a high functionality crosslinker 150 such that, when the hybrid copolymer composition 100 is cured in a continuous roll-to-roll process, the hybrid copolymer composition 100 exhibits optical clarity (e.g., an optical transmission of greater than 90% and/or voids with a characteristic size less than 100 nanometers); impact resistance (e.g., a storage modulus between 100 MPa and 400 MPa at 20° C.); mechanical stability between −20° C. and 85° C. (e.g., a storage modulus between 400 and 1400 MPa at −20° C. and a storage modulus between 10 and 100 MPa at 85° C.); flexibility/foldability (e.g., a repeatable 1-millimeter bend radius), and UV stability. Furthermore, in prepolymer form, the hybrid copolymer composition 100 is workable via a roll-to-roll manufacturing process, such as described in U.S. application Ser. No. 15/895,971. When manufactured as a thin film, the hybrid copolymer composition 100 can function as a protective layer 102 in a foldable electronic display (or touchscreen), thereby protecting a display layer in the foldable electronic display from damage due to impact, scratching, or abrasion while maintaining its optical and mechanical properties after repetitive flexion (e.g., folding) of the display. Additionally and/or alternatively, the hybrid copolymer composition 100 can function as a sponge film 103 configured to provide impact resistance to a mechanical housing of a foldable electronic display. Thus, without sacrificing optical properties, the hybrid copolymer composition 100 exhibits improved impact resistance and durability to repetitive flexion of foldable and/or foldable electronic displays as compared to other foldable display technology. For example, a foldable electronic display including a protective layer 102 manufactured from the hybrid copolymer composition 100 may exhibit minimal optical and mechanical changes when folded with a 2-millimeter bend radius 200,000 times.

The hybrid copolymer composition 100 can exhibit the abovementioned properties by effectively combining: qualities of aliphatic isocyanate-polyol polymers, such as UV stability and slower reaction rates during polymerization, qualities of aromatic isocyanate-polyol polymers, such as high elongation at break, and qualities of polyureas, such as flexibility and durability. Furthermore, the hybrid copolymer composition 100 includes: a curative 130 that yields a relatively long polymer chain length in the hybrid copolymer composition 100; and a high functionality crosslinker 150 that yields a high bulk crosslink density in the hybrid copolymer composition 100. More specifically, the curative 130 is configured to extend a chain length of the polyisocyanate-terminated polyol 110 and the additional polyisocyanates 120 via polyurea linkages 106 and the high functionality crosslinker 150 is configured to crosslink the polyisocyanate-terminated polyol 110 and additional polyisocyanates in a radially-integrated pattern via polyurethane linkages 104, thereby providing greater storage modulus at higher temperatures while maintaining flexibility at lower temperatures. The hybrid copolymer composition 100 also includes the soft polymer chain 140 which is configured to polymerize with the polyisocyanate terminations 114 of the polyisocyanate-terminated polyol 110 and the additional polyisocyanates 120 to control crystallization of the polyisocyanate-terminated polyol 110 at low temperatures, thereby providing lower storage modulus at low temperatures when compared with typical polyurethane compositions.

In one implementation, as shown in FIG. 2, the hybrid copolymer composition 100 includes an aliphatic-diisocyanate-terminated polyol 111 as the polyisocyanate-terminated polyol 110; additional diisocyanates 121 as the additional polyisocyanates 120; an aromatic diamine curative 131 as the curative 130; a polyester polyol 141 as the soft polymer chain 140; and a high functionality dendrimer 151 as the high functionality crosslinker 150.

The hybrid copolymer composition 100 can include a catalyst, which aids in improving processing times. The catalyst can include any polyurethane catalyst configured to initiate polyurethane and/or polyurea polymerization that does not present environmental health and safety concerns during the manufacturing process or in the completed product (e.g., when included in a light-emitting diode display). Additionally, the hybrid copolymer composition 100 can include additives, including but not limited to surfactants, de-foamers, self-leveling agents, and/or wetting agents, which can reduce the surface tension of the prepolymer mixture and thereby improve the surface quality of a protective film manufactured from the hybrid copolymer composition 100.

Furthermore, the prepolymer mixture of the hybrid copolymer composition 100 is soluble in aprotic, polar organic solvents, such as methyl ethyl ketone (hereinafter “MEK”), which can substantially evaporate during the roll-to-roll manufacturing process while reducing the viscosity of the prepolymer mixture.

### 3. Foldable Display

In one implementation, the hybrid copolymer composition 100 can be configured to form a protective film layer 102 in a foldable electronic display. As shown in FIG. 3A, the hybrid copolymer composition 100 can be configured to form a protective film layer 102 for a foldable electronic display, the foldable electronic display including: a foldable light-emitting diode (hereinafter “LED”) display (e.g., an array of organic light emitting diodes); and a cover layer. The protective film layer 102 includes: a first proportion of the polyisocyanate-terminated polyol 110; the second proportion of additional polyisocyanates 120; a third proportion of the curative 130; a fourth proportion of the soft polymer chain 140; and the fifth proportion of a high functionality crosslinker.

In one implementation, the foldable electronic display includes a protective film layer 102 arranged above the cover layer and secured via an optically clear adhesive as shown in FIG. 3A. In another implementation, the foldable electronic display includes a protective film layer 102 arranged between the cover layer and the foldable electronic display as shown in FIG. 3C. In yet another implementation, the foldable electronic display includes a first protective film layer 102 arranged above the cover layer and a second protective film layer 102 arranged beneath the cover layer both secured via layers of optically clear adhesive. Additionally or alternatively, the foldable electronic display can include optically clear adhesive to adhere the cover layer to the protective film or the protective film layer 102 to the foldable electronic display.

The hybrid copolymer composition 100 can be manufactured via a roll-to-roll manufacturing process to form a protective film 102 configured for insertion in a foldable electronic display stack. For example, the hybrid copolymer composition 100 can form a protective film exhibiting: a thickness between 5 micrometers and 100 micrometers; and a flexibility characterized by bending the film layer around a two-millimeter millimeter mandrel, unfolding the film, and observing no damage or change in the protective film 102 after repeating this process over 200,000 times. Additionally, the protective film 102 exhibits desirable optical qualities including: transmission greater than ninety percent; haze less than one percent; and clarity greater than ninety percent.

In another implementation, as shown in FIG. 3B, the hybrid copolymer composition 100 can be manufactured to form a sponge layer 103 in a foldable electronic display, the foldable electronic display including: a foldable light-emitting diode (hereinafter “LED”) display; and a mechanical housing arranged below the LED display and above the sponge layer 103. Additionally or alternatively, the foldable electronic display can include a pressure sensitive adhesive layer; For example, the hybrid copolymer composition 100 can form the sponge layer 103 exhibiting: a thickness between 5 micrometers and 100 micrometers; and an elongation at break greater than 400 percent.

However, a foldable electronic display including the protective film layer 102 or the sponge layer 103 can include additional layers or components not described above or shown in FIGS. 3A, 3B, and 3C. Alternatively, a foldable electronic display including the protective film layer 102 or the sponge layer 103 can include fewer layers or components shown in FIGS. 3A, 3B, and 3C.

### 4. Polymer Properties

The polymerized form of the hybrid copolymer composition 100 exhibits qualities that are favorable for use as a protective film (i.e. protective layer 102) within an electronic display. More specifically, the polymerized form of the hybrid copolymer composition 100 exhibits qualities favorable for insertion as a protective film layer 102 within a foldable electronic display, such as an LED display (e.g., an organic LED display). Therefore, the polymer form of the hybrid copolymer composition 100 exhibits: higher storage modulus at high temperatures and lower storage modulus at lower temperatures than a typical polyurethane-based or poly(urea-urethane)-based elastomer, thereby enabling a thin film of the hybrid copolymer composition 100 (e.g., with a thickness between 5 and 100 micrometers) to protect the electronic display from impact, scratching, and abrasion over a wide range of temperatures (−20° C. to 85° C.); high flexibility, thereby enabling the hybrid copolymer composition 100 to repeatedly bend around a small radius without noticeable deformation or degradation; optical clarity, which enables a user to view an image rendered on the electronic display without significant optical aberrations; and UV stability, thereby preserving perceived color of images rendered by the underlying electronic display.

The polymerized hybrid copolymer composition 100 can exhibit a storage modulus between 100 MPa and 400 MPa at 20° C. (as measured via dynamic mechanical analysis testing using a tension clamp from −70° C. and ° C. with a 2° C./min warming rate, an oscillation rate of 1 Hz, and a force control of 0.1 N), depending on factors (further discussed below) including: the functionality and weight percentage of the curative 130 included in the hybrid copolymer composition 100; the molecular weight and type of the polyol in the polyisocyanate terminated polyol 110; the weight percentage and chemistry of the additional polyisocyanates 120; the molecular weight and weight percentage of the soft polymer chain 140; and the weight percentage and degree of functionality of the high functionality crosslinker 150.

The polymerized hybrid copolymer composition 100 can exhibit relatively low variation in storage modulus over its operating temperature range. For example, the hybrid copolymer composition 100 can exhibit a storage modulus between 400 MPa and 1400 MPa at −20° C., a storage modulus between 100 and 400 MPa at −20° C., and a storage modulus between 10 MPa and 100 MPa at 85° C. Furthermore, the polymerized hybrid copolymer composition 100 can exhibit a relatively high glass transition temperature, such as between 40° C. and 75° C. (as measured via dynamic mechanical analysis testing using a tension clamp from −70° C. to 150° C. with a 2° C./min heating rate, an oscillation rate of 1 Hz, and a force control of 0.1 N). The low variation in storage modulus and high glass transition temperature of the hybrid copolymer composition 100 results in part from the hybrid nature of the copolymer, wherein hard polymer segments include the isocyanate terminations 114 of the polyisocyanate-terminated polyol 110, the additional polyisocyanates 120, and the curative 130 chain extender; and wherein soft polymer segments include the polyol segments of the polyisocyanate-terminated polyol 110 and the soft polymer segment. Generally, the hard polymer segments maintain the rigidity of the hybrid copolymer composition 100 at high temperatures while the soft polymer segments prevent excess hardening of the hybrid copolymer composition 100 at low temperatures. Thus, temperature-dependent storage modulus characteristics of the hybrid copolymer composition 100 may be tuned by adjusting the weight percentage of the hard polymer segment components in relation to the weight percentage of the soft polymer segment components.

The polymerized hybrid copolymer composition 100 can also exhibit high static and dynamic flexibility. The static flexibility of the polymerized hybrid copolymer can be characterized by bending a thin film of the hybrid copolymer composition 100 around a 2-millimeter radius mandrel for four hours at 25° C. without the thin film of the hybrid copolymer composition 100 exhibiting permanent deformation or degradation of optical or mechanical properties. The dynamic flexibility of the polymerized hybrid copolymer composition 100 can be characterized by repeatedly bending the thin film of the hybrid copolymer composition 100 around a 2-millimeter radius mandrel at a frequency of 1 Hz for 200,000 cycles without the thin film of the hybrid copolymer composition 100 exhibiting permanent deformation or degradation of optical or mechanical properties. The flexibility and/or foldability of the hybrid copolymer composition 100 may be tuned, in part, by adjusting the proportions of the curative 130 and the high functionality crosslinker 150, which affects the bulk crosslinking density of the hybrid copolymer composition 100. Furthermore, the flexibility and/or foldability of the hybrid copolymer composition 100 can be modified by adjusting the molecular weight and type of the polyol in the polyisocyanate terminated polyol 110; the weight percentage and chemistry of the additional polyisocyantes 120; the molecular weight type and weight percentage of the soft polymer chain 140; and the weight percentage of the high functionality crosslinker 150.

Furthermore, the polymerized hybrid copolymer can exhibit high optical clarity. For example, the polymerized hybrid copolymer composition 100 can exhibit optical transmission greater than 90%, haze less than 1.0%, clarity greater than 90%; and CIE 1976 Color Scale values of L* greater than 90, a* greater than −1.0 and less than 1.0, and b* greater than −1.0 and less the 1.0. The optical properties are enabled by the amorphous structure of the soft polymer segment of the hybrid copolymer composition 100 and control over the degree of crystallinity and crystallite size of the hard segment.

However, the polymerized hybrid copolymer composition 100 may exhibit properties different than those described above manufactured with an alternative manufacturing method (e.g., such as spray coating).

### 5. Prepolymer Properties

The prepolymer form of the hybrid copolymer composition 100 also exhibits qualities that are favorable to thin-film manufacturing techniques, such as a roll-to-roll manufacturing process. Therefore, the prepolymer form of the hybrid copolymer composition 100 exhibits: low viscosity, thereby enabling the prepolymer mixture to be distributed via a slot-die and to self-level within a reasonable manufacturing time; solubility in commonly used organic solvents in the coatings field; low surface tension such that the prepolymer mixture cures without the appearance of flow lines and other surface defects; and a sufficiently long pot-life to enable coating with a slot die.

The prepolymer form of the hybrid copolymer composition 100 exhibits a viscosity less than 3500 centipoise, such that a thin film of the hybrid copolymer composition 100 can be coated and fully or partially cured using a roll-to-roll manufacturing process. The viscosity of the prepolymer form of the hybrid copolymer composition 100 is controlled by adjusting the weight percentage in a solvent (e.g., a smaller weight percent resulting in a lower viscosity), which may be adjusted between 20% and 80% solids, depending on the particular solvent included in the prepolymer mixture; solvent type, and the bulk molecular weight of the components of the prepolymer form of the hybrid copolymer composition 100.

The prepolymer form of the hybrid copolymer composition 100 also exhibits a low surface tension due to the inclusion of additives, including but not limited to surfactants, de-foamers, self-leveling agents, and/or wetting agents. Therefore, the hybrid copolymer composition 100 exhibits a negative correlation between the weight percentage of the additives and the surface tension of the prepolymer mixture.

Furthermore, the prepolymer form of the hybrid copolymer composition 100 also exhibits a tuned pot-life that is long enough such that the prepolymer mixture can be coated using a slot-die without curing prematurely, while also being short enough to mitigate any imprinting defects due to insufficient curing and/or incomplete drying during the combined drying/curing process. The pot-life of the prepolymer mixture is controlled by: the weight proportion and chemistry of the catalyst; temperature; the weight proportion of the aliphatic or mixture of aliphatic and aromatic polyisocyanate 120; the overall solids content (i.e. the number of reactive species) of the prepolymer; and the ratio of polyurea linkage to polyurethane linkage generating groups in the prepolymer.

However, the prepolymer form of the hybrid copolymer composition 100 can be tuned to exhibit different viscosities, different surface tensions, and/or different pot-lives for other polymer manufacturing processes, such as spray-coating, dip-coating, moulding, compressing, transferring, injecting, blowing, or other roll-to-roll processes such as gravure, reverse gravure, micro gravure, reverse roll, flex bar, rod, wire bar, knife over roll coating, etc.

### 6. Hybrid Copolymer Composition

As shown in FIGS. 1A and 1B, the hybrid copolymer composition 100 is a crosslinked copolymer containing hard polymer segments and soft polymer segments resulting from the polymerization of molecular components including: a first proportion of polyisocyanate-terminated polyol 110; a second proportion of additional polyisocyanates 120; a third proportion of curative 130 (or “chain length extender”); a fourth proportion of soft polymer chain 140; and a fifth proportion of high functionality crosslinker 150. The hybrid copolymer composition 100 can also include a catalyst and additives, such as wetting agents, de-foamers, surfactants, etc. to improve the prepolymer properties of the hybrid copolymer composition 100, as described above, for thin film manufacturing techniques.

In one implementation, the hybrid copolymer composition 100 includes an aliphatic-diisocyanate-terminated polyol 111 as the polyisocyanate-terminated polyol 110, a mixture of aliphatic polyisocyanate and aromatic polyisocyanate as the additional polyisocyanates 120, an aromatic diamine curative 131 as the curative 130, a polyester polyol 141 as the soft polymer chain 140, and a high functionality dendrimer 151 as the high functionality crosslinker 150. Thus, in this implementation, the hybrid copolymer composition 100 includes: a first proportion of an aliphatic-diisocyanate-terminated polyol 111; a second proportion including aliphatic polyisocyanate and aromatic polyisocyanate; a third proportion of an aromatic diamine curative 131 configured to extend a chain length of the aliphatic-diisocyanate-terminated polyol 111, the aliphatic polyisocyanate, and the aromatic polyisocyanate; a fourth proportion of a polyester polyol 141 configured to polymerize with the aliphatic-diisocyanate-terminated polyol 111, the aliphatic polyisocyanate, and the aromatic polyisocyanate; and a fifth proportion of a high functionality dendrimer 151 configured to crosslink the aliphatic-diisocyanate-terminated polyol 111, the aliphatic polyisocyanate, and the aromatic polyisocyanate.

Different combinations of polymers and isocyanate terminations 114 can be included in these proportions of the hybrid copolymer composition 100 in order to achieve the desired mechanical and optical characteristics. For example, in a first implementation, the hybrid copolymer composition 100 can include: a 12-fold-hydrogenated-methylene-diphenyl-diisocyanate-terminated polybutylene adipate as the polyisocyanate-terminated polyol; an isophorone diisocyanate as the aliphatic polyisocyanate 120; hydroquinone bis(2-hydroxyethyl)ether as the curative 130; a polyester polyol 141 as the soft polymer chain 140; and a dendritic polyester polyol exhibiting a functionality of six as the high functionality crosslinker 150. Thus, in this implementation, the hybrid copolymer composition 100 includes: a first proportion of 12-fold-hydrogenated-methylene-diphenyl-diisocyanate-terminated polybutylene adipate; a second proportion of isophorone diisocyanate; a third proportion of hydroquinone bis(2-hydroxyethyl)ether; a fourth proportion of a polyester polyol 141; and a fifth proportion of a dendritic polyester polyol exhibiting a functionality of six.

In a second implementation, the hybrid copolymer composition 100 can include: a 12-fold-hydrogenated-methylene-diphenyl-diisocyanate-terminated poly(tetramethylene ether) glycol as the polyisocyanate-terminated polyol 110; a mixture of 12-fold-hydrogenated-methylene-diphenyl-diisocyanate 122 and a tetramethylxylene diisocyanate 123 as the additional polyisocyanate; a set of isomers of diethyl toluene diamine 131 as the curative 130; a polycaprolactone polyol diol 141 as the soft polymer chain 140; and a dendritic polyester polyol 151 exhibiting a functionality greater than five as the high functionality crosslinker 150. Thus, in this implementation, the hybrid copolymer composition 100 includes: a first proportion of a 12-fold-hydrogenated-methylene-diphenyl-diisocyanate-terminated poly(tetramethylene ether) glycol 111; a second proportion of additional polyisocyanates 120 including a first quantity of 12-fold-hydrogenated-methylene-diphenyl-diisocyanate 122 and a second quantity of tetramethylxylene diisocyanate 123; a third proportion of a set of isomers of diethyl toluene diamine 131; a fourth proportion of a polycaprolactone polyol diol 141; and a fifth proportion of an alcohol-terminated dendrimer 151 exhibiting a functionality greater than five.

In a third implementation, the hybrid copolymer composition 100 can include: an isophorone diisocyanate poly(tetramethylene ether)glycol as the polyisocyanate-terminated polyol 110; a mixture of tetramethylxylene diisocyanate 123 and 12-fold-hydrogenated-methylene-diphenyl-diisocyanate 122 as the additional polyisocyanate 120; diethyl toluene diamine 131 as the curative 130; a linear polyester diol as the soft polymer chain 140; a dendritic polyester polyol exhibiting a functionality of sixteen as the high functionality crosslinker 150. Thus, in this implementation, the hybrid copolymer composition 100 includes: a first proportion of isophorone diisocyanate poly(tetramethylene ether) glycol; a second proportion of additional polyisocyanates 120 including a first quantity of tetramethylxylene diisocyanate 123 and a second quantity of 12-fold-hydrogenated-methylene-diphenyl-diisocyanate 122; a third proportion of diethyl toluene diamine 131; a fourth proportion of a linear polyester diol; and a fifth proportion of a dendritic polyester polyol exhibiting a functionality greater than sixteen.

Various implementations of the hybrid copolymer composition 100 can contain different weight percentages of each of the aforementioned components depending on the desired properties of both the prepolymer form and polymerized form of the hybrid copolymer composition 100. However, in implementations of the hybrid copolymer composition 100 for use as a protective film layer 102 or sponge layer 103 in an foldable electronic display, the hybrid copolymer composition 100 can include: a first weight proportion of polyisocyanate-terminated polyol 110 between 50% and 90%; a second weight proportion of additional polyisocyanates 120 of up to 10%; a third weight proportion of a curative 130/chain length extender between 2% and 25%; a fourth weight proportion of a soft polymer chain 140 of up to 30%; and a fifth weight proportion of high functionality crosslinker 150 of up to 5%. In implementations of the hybrid copolymer composition 100 that include the catalyst, the hybrid copolymer composition 100 can include a sixth proportion of the catalyst of up to 2%. In implementations of the hybrid copolymer composition 100 that include additives, the hybrid copolymer composition 100 can include a seventh weight proportion of additives of up to 3%. In implementations of the hybrid copolymer composition 100 that are colored, the hybrid copolymer composition 100 can include an eighth proportion of nanoparticle pigment and/or organic colored dyes between 1% and 15% by weight.

In one implementation, the hybrid copolymer composition 100 includes: fifty-five percent to eighty percent of the first proportion of polyisocyanate-terminated polyol 110 by weight; one percent to ten percent of the second proportion of additional polyisocyanate 120 by weight; one percent to ten percent of the third proportion of the curative 130 by weight; fifteen percent to thirty percent of the fourth proportion of the soft polymer chain 140 by weight; and zero to five percent of the fifth proportion of the high functionality crosslinker 150 by weight. Further, the hybrid copolymer composition 100 can include up to one percent of a sixth proportion of a catalyst (e.g., dibutyltin dilaurate) by weight.

The hybrid copolymer composition 100 is a polyurethane-polyurea polymer composition including the aforementioned components which polymerize to form crosslinked hard polymer segments and soft polymer segments via a first number of polyurethane linkages 104 and a second number of polyurea linkages 106. The polyurethane linkages connect (i.e. chemically bond): the polyol chains 116 of the polyisocyanate terminated polyol 110 to the polyisocyante terminations 114 of the polyisocyanate terminated polyol 110; the soft polymer chain 140 to the polyisocyanate terminations 114 and the additional polyisocyanates 120; and the high functionality crosslinker to the polyisocyanate terminations 114 and the additional polyisocyanates 120. The polyurea linkages 106 connect the curative 130 to the polyisocyanate terminations 114 and the additional polyisocyanates 120.

Thus, polyurethane groups link soft polymer segments (including the polyisocyanate terminated polyol 110, the soft polymer chain 140, and the additional polyisocyanates 120) within the hybrid copolymer composition 100 and crosslink (e.g., via the high functionality crosslinker) the soft polymer segments with the hard polymer segments while polyurea groups link the hard polymer segments (including the curative 130, the additional polyisocyanates 120, and the polyisocyanate terminations) within the hybrid copolymer composition. The copolymerization of these multiple forms of soft polymer segments in the hybrid copolymer composition 100 prevents the hybrid copolymer composition 100 from hardening at lower temperatures while the inclusion of the hard polymer segments in the hybrid copolymer composition 100 maintains the rigidity of the hybrid copolymer composition 100 at higher temperatures.

More specifically, the hybrid copolymer composition 100 can include a tuned ratio of polyurethane linkages 104 to polyurea linkages 106. The polyurethane linkages 104 in the hybrid copolymer composition 100 connect a first quantity of polyether polyol 116 segments to a second quantity of aliphatic diisocyanate terminations 114; connect a third quantity of polyester polyol 141 segments to the second quantity of the aliphatic diisocyanate terminations 114 and a fourth quantity of additional diisocyanates 120; and connect a fifth quantity of a high functionality crosslinker 150 to the second quantity of the aliphatic diisocyanate terminations 114 and the fourth quantity of additional diisocyanates 120. The polyurea linkages 106 in the hybrid copolymer composition 100 connect a sixth quantity of an aromatic polyamine curative 131 to the second quantity of the aliphatic diisocyanate terminations 114 and the fourth quantity of additional diisocyanates 120.

The hybrid copolymer composition 100 is configured to include both polyurethane linkages 104 and polyurea linkages 106 in order to achieve the desired mechanical properties (e.g., storage modulus, tensile modulus, bendability) and optical clarity (e.g., optical transmission, void size and fraction). Thus, the hybrid copolymer composition 100 can also define a ratio of polyurethane linkages 104 to polyurea linkages 106 that yields these desired properties. For example, the hybrid copolymer composition 100 can define a molar ratio of polyurethane linkages 104 to polyurea linkages 106 between two-to-five and six-to-five.

However, the hybrid copolymer composition 100 can also include additional components or modified proportions of the above components that may improve the properties of the hybrid copolymer composition 100 when applied as a protective layer in a foldable electronic display.

### 6.1 Polyisocyanate-Terminated Polyol

The hybrid copolymer composition 100 includes a first proportion of polyisocyanate-terminated polyol 110 (e.g., a polyester, polycaprolactone, polyether, polyacrylate, or polycarbonate) as the largest weight proportion of the hybrid copolymer composition 100. For example, the hybrid copolymer composition 100 can include between fifty-five percent and eighty percent of the first proportion of polyisocyanate-terminated polyol 110 by weight. The polyisocyanate-terminated polyol 110 includes two subcomponents in each prepolymer chain: the polyisocyanate-terminations 114 and the polyol chain 116. The polyisocyanate-terminations 114 function as a component in hard polymer segments of the hybrid copolymer composition 100, when reacted with the curative 130, the soft polymer chain 140, and/or the high functionality crosslinker 150, while the polyol chain 116 functions as a soft linkage between the hard segments. When reacted, the polyisocyanate-terminations and the polyol chain 116 bond to form urethane linkages. In one implementation, the polyisocyanate-terminated polyol 110 includes a diisocyanate-terminated polyether polyol with an average molecular weight between 650 and 2600 g/mol. In a second implementation, the polyisocyanate-terminated polyol 110 includes a diisocyanate-terminated polyester polyol with an average molecular weight between 500 and 2600 g/mol. Thus, the polyisocyanate-terminated polyol 110 provides the chemical backbone of the hybrid copolymer composition 100.

The hybrid copolymer composition 100 can include different quantities of different average molecular weight of the polyol chain 116 in the first proportion of the polyisocyanate-terminated polyol 110. In one implementation, the hybrid copolymer composition 100 includes a first proportion of a polyisocyanate-terminated polyol 110 including: a first quantity of the polyol chain 116 exhibiting a first average molecular weight; and a second quantity of the polyol chain 116 exhibiting a second average molecular weight. Further, based on the first quantity of the polyol chain 116 and the second quantity of the polyol chain 116, the hybrid copolymer composition 100 can exhibit a low temperature storage modulus between 400 MPa and 1400 MPa and a high temperature storage modulus between 10 MPa and 100 MPa.

In one implementation, the hybrid copolymer composition 100 exhibits properties of a copolymer including both lower average molecular weight polyols (e.g., 650 g/mol) and higher average molecular weight polyols (e.g., 2,000 g/mol) by including blends of the polyisocyanate-terminated polyol 110 including polyol chains 116 with a range of molecular weights. For example, the hybrid copolymer composition 100 can include a first proportion of aliphatic-diisocyanate-terminated polyol in including: a first quantity of polyol chain 116 exhibiting an average molecular weight of 650 g/mol; a second quantity of polyol chain 116 exhibiting an average molecular weight of 1,000 g/mol; and a third quantity of polyol chain 116 exhibiting an average molecular weight of 2,000 g/mol. Thus, by including varying average molecular weights, the hybrid copolymer composition 100 can exhibit properties of both lower average molecular weight and higher average molecular weight polyols.

The average molecular weight of the first proportion of polyisocyanate-terminated polyol 110 may be increased to lower the low temperature storage modulus of the hybrid copolymer composition 100. For example, the hybrid copolymer composition 100 can include: a first proportion of an aliphatic-diisocyanate-terminated polyol 111 including a first quantity of the polyol chain 116 characterized by an average molecular weight of 650 g/mol, the first quantity defining between ninety percent and one-hundred percent of the first proportion by weight. The hybrid copolymer composition 100 can exhibit: a low temperature storage modulus between 900 MPa and 1400 MPa; and a high temperature storage modulus between 20 MPa and 30 MPa. Alternatively, in another example, the hybrid copolymer composition 100 can include a first proportion of an aliphatic-diisocyanate-terminated polyol 111: including a first quantity of the polyol chain 116 characterized by an average molecular weight of 650 g/mol, the first quantity defining between sixty percent and eighty percent of the first proportion by weight; and a second quantity of the polyol chain 116 characterized by an average molecular weight of 2000 g/mol, the second quantity defining between twenty percent and forty percent of the first proportion by weight. In this example, the hybrid copolymer composition 100 can exhibit: a low temperature storage modulus between 500 MPa and 800 MPa; and a high temperature storage modulus between 15 MPa and 25 MPa. Thus, the low temperature modulus of the hybrid copolymer composition 100 may be lowered by increasing the average molecular weight of the polyisocyanate-terminated polyol 110.

The hybrid copolymer composition 100 can include a polyisocyanate-terminated polyol 110 with polyisocyanate-terminations with an overall functionality equal to or greater than two, where polyisocyanate-terminations with greater functionality increase the storage modulus of the hybrid copolymer composition 100 by increasing the degree of crosslinking. In one implementation, the hybrid copolymer composition 100 includes a diisocyanate-terminated polyol exhibiting an overall functionality of two, thus reducing the storage modulus of the hybrid copolymer composition 100 at lower temperatures (e.g., −20° C.) when compared to polyisocyanates exhibiting higher overall functionality (e.g., greater than two). For example, the hybrid copolymer composition 100 can: include a diisocyanate-terminated polyol exhibiting an overall functionality of two and including a polyol chain 116 bonded with a first diisocyanate on a first end and bonded with a second diisocyanate on a second end. The functional group of the diisocyanate terminations not bound to the polyol chain 116 can additionally bond to one of a curative 130, a soft polymer chain 140, or a high functionality crosslinker 150. In this implementation, the hybrid copolymer composition exhibits a low temperature storage modulus between 400 MPa and 1000 MPa.

Additionally, the hybrid copolymer composition 100 can include a polyisocyanate-terminated polyol 110 with either aromatic or aliphatic polyisocyanate 120-terminations (or a blend thereof) depending on the desired characteristics of the hybrid copolymer composition 100, wherein polyisocyanate-terminated polyol 110 including aromatic terminations are generally characterized by improved impact and scratch resistance and high-temperature bend performance, while polyisocyanate-terminated polyols no including aliphatic terminations are generally characterized by improved optical clarity, low-temperature bend performance, and longer pot-life. In one implementation, the hybrid copolymer composition 100 includes a proportion of aromatic polyisocyanate-terminated polyol 110 and a proportion of aliphatic polyisocyanate-terminated polyol 110 to achieve more balanced characteristics representative of both aromatic and aliphatic-polyisocyanate terminations 114. In one implementation, as shown in FIG. 2, the hybrid copolymer composition 100 includes a polyisocyanate-terminated polyol 110 terminated by 12-fold hydrogenated methylene diphenyl diisocyanate (hereinafter “H12 MDI”), which is an aliphatic diisocyanate. In alternative implementations, the polyisocyanate-terminated polyol 110 can include other isocyanate terminations 114, such as isophorone diisocyanate (hereinafter “IPDI”) and/or hexamethylene diisocyanate (hereinafter “HDI”).

The polyisocyanate-terminated polyol 110 can include a variety of polyol chains 116 common in various foldable polyurethanes, such as polyether polyols, polyester polyols, polycaprolactone polyols, polyacrylic polyols, and polycarbonate polyols. In one implementation, the polyisocyanate-terminated polyol 110 includes poly(tetramethylene ether) glycol (hereinafter “PTMEG”) as the polyol chain 116.

In one implementation, as shown in FIG. 2, the hybrid copolymer composition 100 includes H12 MDI terminated PTMEG as the polyisocyanate-terminated polyol 110. In a second implementation, the hybrid copolymer composition 100 includes H12 MDI terminated polybutylene adipate (polyester) as the polyisocyanate terminated polyol.

In one variation, the first proportion of polyisocyanate-terminated polyol 110 further includes polyol chains 116 terminated by a first set of diisocyanates; and a second set of diisocyanates (e.g., additional isocyanates 120) configured to promote polymerization of the third proportion of the curative 130, the fourth proportion of soft polymer chains 140, and the fifth proportion of the high functionality crosslinker 150. For example, the hybrid copolymer composition 100 can include the first proportion of aliphatic-diisocyanate-terminated polyol 111 including polyol chains 116 terminated by a first set of aliphatic diisocyanates and a second set of aliphatic diisocyanates configured to promote polymerization of the third proportion of the curative 130, the fourth proportion of the soft polymer chains 140, and the fifth proportion of the high functionality crosslinker; and exhibiting a molar ratio of the first set of diisocyanates to the second set of diisocyanates between two and four. In this example, the second set of aliphatic diisocyanates perform a similar function (e.g., promote polymerization between soft segments and/or hard segments) to the second proportion of the aliphatic polyisocyanate 120, as described below.

### 6.2 Additional Polyisocyanates

The hybrid copolymer composition 100 includes a second proportion of additional polyisocyanates 120 configured to increase mechanical strength and rigidity of the hybrid copolymer composition 100. More specifically, the hybrid copolymer composition 100 includes a second proportion of additional polyisocyanates 120 (i.e. polyisocyanates that do not terminate polyol chains as described above) and can include a quantity of aliphatic polyisocyanates or a mixture of a quantity of aliphatic polyisocyanates and a quantity of aromatic polyisocyanates. The inclusion of the additional polyisocyanates 120 functions to further modify the hard polymer segments and soft polymer chains 140 to achieve specific material property targets, such as increased scratch and/or impact resistance (in implementations of the hybrid copolymer composition including the additional polyisocyanates includes aromatic isocyanates). Furthermore, the incorporation of sterically hindered urethane groups in the additional polyisocyanates 120 improves processability by reducing side reactions with water in the prepolymer mixture and enabling well-controlled reactions between the prepolymer mixture and hydroxyl and/or amine groups. The hybrid copolymer composition can include between one and ten percent of the aliphatic isocyanate by weight.

Like the polyisocyanate-terminated polyol 110, the additional polyisocyanates 120 can exhibit an overall functionality equal to or greater than two, wherein additional polyisocyanates 120 with greater functionality increase the storage modulus of the hybrid copolymer composition 100 by increasing the degree of crosslinking. In one implementation, the hybrid copolymer composition 100 includes an aliphatic diisocyanate as the additional polyisocyanate 120.

In one implementation, the hybrid copolymer composition 100 can include H12 MDI, as the additional isocyanates 120, as the H12 MDI increases the storage modulus of the hybrid copolymer composition 100 at high temperatures without substantially increasing the storage modulus at low temperatures. For example, the hybrid copolymer composition 100 can include a second proportion of H12 MDI defining between two percent and twenty percent of a mixture of the first proportion and the second proportion by weight. In this example, the hybrid copolymer composition 100 can include the second proportion of H12 MDI exhibiting a functionality of two and configured to polymerize with the third proportion of the curative 130/chain length extender, the fourth proportion of the soft polymer chain 140, and/or fifth proportion of the high functionality crosslinker 150. Therefore, in this implementation, the hybrid copolymer composition 100 can include both a first proportion of H12 MDI terminated polyol including H12 MDI terminations, and a second proportion of H12 MDI as the additional polyisocyanates 120.

In another implementation, hybrid copolymer composition 100 can include IPDI as the additional polyisocyanates 120, as IPDI can increase the tensile and storage modulus of the hybrid copolymer composition 100 without substantially increasing the storage modulus at low temperatures. Furthermore, IPDI reduces the viscosity of the prepolymer mixture compared to prepolymer mixtures containing H12 MDI.

In another implementation, as shown in FIG. 2, the hybrid copolymer composition 100 can include a quantity of tetramethylxylene diisocyanate (hereinafter “TMXDI”), as the TMXDI has a low reactivity when compared to aliphatic polyisocyanates such as H12 MDI, and imparts UV stability to the hybrid copolymer composition 100. Additionally, TMXDI increases the storage modulus of the hybrid copolymer composition 100 at high temperatures without substantially increasing the storage modulus at low temperatures by improving the stiffness of hard segments in the hybrid copolymer composition 100. Furthermore, TMXDI reduces the viscosity of the prepolymer mixture more effectively than other common aliphatic polyisocyanates and prevents discoloration of the hybrid copolymer composition 100 (e.g., yellowing of the protective film layer 102).

In yet another implementation, the hybrid copolymer composition 100 includes both TMXDI and excess H12 MDI (i.e. H12 MDI that does not terminate the polyisocyanate-terminated polyol 110) providing a mixture of the abovementioned properties of the hybrid copolymer composition 100 when including TMXDI and H12 MDI separately. For example, the hybrid copolymer composition 100 can include a second proportion of aliphatic polyisocyanate 120 including a mixture of TMXDI and H12 MDI, the second proportion configured to: increase the tensile and storage modulus of the hybrid copolymer composition 100 without substantially increasing the storage modulus at low temperatures; impart UV stability to the hybrid copolymer composition 100; and reduce the viscosity of the prepolymer mixture. In this implementation, the hybrid copolymer composition 100 can include between zero percent and fifteen percent additional H12 MDI by weight and between zero and ten percent TMXDI by weight. The hybrid copolymer composition can include the second proportion of aliphatic isocyanate defining a molar ratio of excess H12 MDI to TMXDI between 0.8 and 2.0. For example, the hybrid copolymer composition can include the second proportion of aliphatic isocyanate defining a molar ratio of excess H12 MDI to TMXDI of one.

### 6.3 Curative and Chain Length Extender

The hybrid copolymer composition 100 includes a third proportion of the curative 130/chain length extender. The curative 130 functions to extend the chain length of hard segments, which include the polyisocyanate terminations 114 of the polyisocyanate-terminated polyols no and the aliphatic polyisocyanate 120, by binding with polyisocyanate terminations 114 via polyurethane bonds and polyurea bonds. Thus, the inclusion of greater proportions of the curative 130 relative to the soft polymer chain 140 of the hybrid copolymer composition 100 increases the storage modulus of the hybrid copolymer composition 100.

In one example, the hybrid copolymer composition 100 can: include a third proportion of the curative 130 defining eleven percent of the hybrid copolymer composition 100 by weight; and include a fourth proportion of the soft polymer chain 140 defining eighteen percent of the hybrid copolymer composition 100 by weight. In this example, the hybrid copolymer composition exhibits a low temperature storage modulus between 700 MPa and 1400 MPa at −20 degrees Celsius; a high temperature storage modulus between 15 MPa and 40 MPa; and a room temperature storage modulus between 100 MPa and 400 MPa at 20 degrees Celsius.

In another example, the hybrid copolymer composition 100 can: include a third proportion of the curative 130 defining eight percent of the hybrid copolymer composition 100 by weight; and include a fourth proportion of the soft polymer chain 140 defining twenty-five percent of the hybrid copolymer composition 100 by weight. In this example, the hybrid copolymer composition 100 exhibits a low temperature storage modulus between 500 MPa and 800 MPa at −20 degrees Celsius; and a high temperature storage modulus between 20 MPa and 30 MPa. Therefore, the hybrid copolymer composition 100 can exhibit a varying range of low temperature and high temperature storage modulus based on the ratio of the curative 130 to the soft polymer chain 140 included in the hybrid copolymer composition 100.

In yet another example, the hybrid copolymer composition 100 includes the third proportion of the curative 130 defining between zero percent and ten percent of the hybrid copolymer composition 100 by weight and exhibits a high temperature storage modulus between 15 MPa and 35 MPa at 85 degrees Celsius. More specifically, where the hybrid copolymer composition 100 includes a lower weight percent of the curative 130 between zero percent and five percent, the hybrid copolymer composition 100 exhibits a high temperature storage modulus between 15 MPa and 25 MPa. Alternatively, where the hybrid copolymer composition 100 includes between five percent and ten percent of the curative 130 by weight, the hybrid copolymer composition exhibits a high temperature storage modulus between 25 MPa and 35 MPa.

The hybrid copolymer composition 100 can include a curative 130 with a low molecular weight (e.g., less than 200 g/mol) configured to increase the number of urethane and/or urea groups per unit length of the hybrid copolymer composition 100. For example, the hybrid copolymer composition 100 can include curatives/chain length extenders such as 1,4 butanediol (e.g., with an average molecular weight of 98.12 g/mol), 2-methyl-1,3-propanediol, diethylene glycol, 1,5-pentanediol, or 1,6 hexanediol.

In one implementation, as shown in FIG. 2, the hybrid copolymer composition 100 includes a polyamine curative such that hard segments of the hybrid copolymer composition 100 include a polyurea chain, thus increasing the number of polyurea groups present in the hybrid copolymer composition 100. Furthermore, the hybrid copolymer composition 100 can include a diamine curative to promote the polymerization of linear polyurea segments 106 when compared to higher functional polyamine curatives. For example, the hybrid copolymer composition 100 can include: a first proportion of H12 MDI terminated PTMEG; a second proportion of additional polyisocyanates (e.g., H12 MDI or H12 MDI and TMXDI); a third proportion of a diamine curative including an aromatic ring and two amine functional groups located opposite each other on the aromatic ring. The hybrid copolymer composition 100 can be configured such that each amine functional group of the second proportion of the diamine curative forms a polyurea bond with a diisocyanate group of the first proportion of H12 MDI terminated PTMEG and/or with aliphatic isocyanates of the second proportion.

The hybrid copolymer composition 100 can also include aromatic curatives, such as aromatic polyamine curatives or aromatic hydroxy-functional curatives, where aromatic polyamine curatives contribute polyurea bond structures to the hybrid copolymer composition 100 and aromatic hydroxy-functional curatives contribute polyurethane bond structures. In one implementation, the hybrid copolymer composition 100 includes one or more isomers of diethyl toluene diamine (hereinafter “DETDA”) as the curative 130, such as 3,5-diethyltoluene-2, 4-diamine; 3,5-diethyltoluene-2, 6-diamine; or a mixture of both. In this implementation, the hybrid copolymer composition 100 can include a proportion of the curative 130 further including a mixture of approximately 80% 3,5-diethyltoluene-2, 4-diamine and approximately 20% 3,5-diethyltoluene-2, 6-diamine. Implementations of the hybrid copolymer composition 100 including DETDA exhibit a high degree of crystallinity and improved high temperature properties when compared to other curatives. In one implementation, the hybrid copolymer composition 100 includes an isomer of DEDTA (e.g., Ethacure 100) with an average molecular weight of 178.28 g/mol and defining between seven percent and ten percent of the hybrid copolymer composition 100 by weight. In this example, the hybrid copolymer composition 100 can exhibit a storage modulus greater than 20 MPa at 85 degrees Celsius.

In another implementation, the hybrid copolymer composition 100 includes hydroquinone bis(2-hydroxyethyl)ether, ethoxylated hydroquinone bis(2-hydroxyethyl)ether or mixtures thereof to enable well-controlled reactions between the prepolymer mixture and curative when compared to compositions including DETDA.

### 6.4 Soft Polymer Chain

The hybrid copolymer composition 100 includes a fourth proportion of a soft polymer chain 140 to prevent excess hardening of the hybrid copolymer composition 100 at low temperatures. The properties of the soft polymer chain 140, such as its weight percentage within the hybrid copolymer composition 100, molecular weight, and chemical backbone type of the soft polymer chain 140 can contribute to the storage modulus characteristics of the hybrid copolymer composition 100. In particular, the molecular weight and composition of the soft polymer chain 140 significantly impact the low temperature storage modulus (e.g., the storage modulus at or below 20 degrees Celsius) of the hybrid copolymer composition 100. Furthermore, in one implementation, a mixture of soft polymer chain 140 backbone chemistries is utilized to control the extent of crystallization of the soft polymer chains 140 at low temperatures and thus control the flexibility of the hybrid copolymer composition 100 at low temperatures. In one implementation, the hybrid copolymer composition 100 includes between fifteen percent and thirty percent of the fourth proportion of the soft polymer chain 140 by weight.

The hybrid copolymer composition 100 can include a secondary polyol as the soft polymer chain 140 that is configured to control crystallization of the polyol chains 116 of the polyisocyanate-terminated polyol 110 by intermixing with the polymer chains of the chain extended polyisocyanate-terminated polyol 110. Thus, the soft polymer chain 140 can reduce the storage modulus of the hybrid copolymer composition 100 at low temperatures without substantially reducing the storage modulus at high temperatures because crystallization of the polyol chains 116 does not occur at high temperatures. For example, the hybrid copolymer composition 100 can include a fourth proportion of the soft polymer chain 140 defining twenty weight percent of the hybrid copolymer composition 100. The hybrid copolymer composition 100 can exhibit a low temperature storage modulus between 800 MPa and 1400 MPa at −20 degrees Celsius and a high temperature storage modulus between 20 MPa and 40 MPa at 85 degrees Celsius. Alternatively, in another example, the hybrid copolymer composition 100 can include a fourth proportion of the soft polymer chain 140 defining thirty weight percent of the hybrid copolymer composition 100. The hybrid copolymer composition 100 can exhibit a low temperature storage modulus between 500 MPa and 800 MPa at −20 degrees Celsius and a high temperature storage modulus between 20 MPa and 40 MPa at 85 degrees Celsius.

In one implementation, as shown in FIG. 2, the hybrid copolymer composition 100 includes a polyester polyol 141 as the soft polymer chain 140, which can further improve the chemical stability of the hybrid copolymer composition 100. In a second implementation, the hybrid copolymer composition 100 includes a polycaprolactone polyol diol with an average molecular weight between 330 and 1000 g/mol as the soft polymer chain 140, which can increase wear resistance, gloss, and UV resistance in addition to decreasing the low temperature storage modulus of the hybrid copolymer composition 100. Alternatively, the hybrid copolymer composition 100 can include other linear polyester diols with an average molecular weight between 500 and 2000 g/mol.

### 6.5 High Functionality Crosslinker

The hybrid copolymer composition 100 includes a fifth proportion of the high functionality crosslinker 150. The high functionality crosslinker 150 functions to increase the crosslinking density of the hybrid copolymer composition 100, thereby improving the high temperature storage modulus of the hybrid copolymer composition 100. The hybrid copolymer composition 100 can include a high functionality crosslinker 150 characterized by functionalities between three and one hundred depending on the desired high temperature shear modulus. For example, the hybrid copolymer composition 100 can include a first high functionality crosslinker 150 characterized by a functionality of five and exhibiting a high temperature storage modulus between 15 MPa and 30 MPa. Alternatively, the hybrid copolymer composition 100 can include a second high functionality crosslinker 150 characterized by a functionality of twenty and exhibiting a high temperature storage modulus between 25 MPa and 40 MPa.

In one implementation, as shown in FIG. 2, the hybrid copolymer composition 100 includes a dendritic polyester polyol as the high functionality crosslinker 150, which, in comparison to a low functionality crosslinker, results in higher crosslinking density in the hybrid copolymer composition 100 for a given weight proportion of crosslinker. Furthermore, the dendritic polyester polyol encourages spatially heterogeneous crosslinking within the soft polymer chain 140 when compared to a low functionality crosslinker used to achieve the same overall bulk crosslink density. The spatially heterogenous crosslinks may improve the low-temperature flexibility of the hybrid copolymer composition 100 by providing a relatively wider distribution of average molecular weight between crosslinks in the hybrid copolymer composition 100 when compared to lower functionality crosslinkers. In one implementation, the hybrid copolymer composition 100 includes a dendritic polyester polyol with a functionality of twenty-three as the high functionality crosslinker 150. In a second implementation, the hybrid copolymer composition 100 includes a dendritic polyester polyol with a functionality of sixteen as the high functionality crosslinker 150. In a third implementation, the hybrid copolymer composition 100 includes a dendritic polyester polyol with a functionality of six as the high functionality crosslinker 150.

### 6.6 Catalyst

The hybrid copolymer composition 100 can also include a sixth proportion of a catalyst. The catalyst functions to promote (during polymerization of the hybrid copolymer composition 100) polyol-isocyanate and/or amine-isocyanate reactions in order to balance the pot-life and reactivity of the prepolymer mixture for a roll-to-roll manufacturing process. Thus, the hybrid copolymer composition 100 can include any catalyst that promotes urethane and/or urea reactions. In one implementation, the hybrid copolymer composition 100 includes tetravalent diorganotins, such as dibutyltin dilaurate (hereinafter “DBTDL”), as the catalyst. In a second implementation, the hybrid copolymer composition 100 includes organozincs, such as zinc neodecanoate, as the catalyst. In a third implementation, the hybrid copolymer composition 100 includes blends of zinc and bismuth catalysts, such as zinc and bismuth carboxylate, as the catalyst.

### 6.7 Surface Additive

The hybrid copolymer composition 100 can also include a seventh proportion of a surface additive. The surface additive functions to reduce the surface tension of the prepolymer mixture of the hybrid copolymer composition 100, thereby improving the surface quality of the cured film of hybrid copolymer composition 100. In one implementation, the hybrid copolymer composition 100 includes a silicone oil surface additive such that the surface additive can be added to the prepolymer mixture of the hybrid copolymer composition 100 independent on the specific solvents included in the prepolymer mixture of the hybrid copolymer composition 100. In a second implementation, the hybrid copolymer composition 100 includes polyether-modified polydimethylsiloxane, which can prevent cratering and increase gloss in a thin film of the hybrid copolymer composition 100. Additional examples of surface additives include, but are not limited to, wetting agents, de-foamers, surfactants, etc.

### 6.8 Prepolymer Solvents

The prepolymer form of the hybrid copolymer composition 100 can include a solvent at between 20% and 80% weight proportion of the prepolymer mixture depending on the manufacturing method and desired drying properties of the prepolymer mixture. The prepolymer form of the hybrid copolymer composition 100 can include a solvent or combination of solvents in which the prepolymer form of the hybrid copolymer composition 100 exhibits sufficient solubility, such as a ketone solvent. More specifically the prepolymer form of the hybrid copolymer composition 100 can include methyl isobutyl ketone (MIBK), cyclohexanone, acetone, and/or MEK. The prepolymer form of the hybrid copolymer composition 100 can include an aprotic, polar organic solvent, in order to reduce the viscosity of the prepolymer form of the hybrid copolymer composition 100. In one implementation, the solvent can also contain smaller proportions of toluene and/or cyclohexanone to improve coating quality during the drying process.

Furthermore, in some manufacturing processes, the prepolymer form of the hybrid copolymer composition 100 can include multiple component mixtures each with a different solvent and/or solvent proportions. For example, the prepolymer form of the hybrid copolymer composition 100 can include a first mixture including the catalyst, the curative 130/chain extender, the soft polymer chain 140, surface additives, and the high functionality crosslinker 150, and a second mixture including the polyisocyanate-terminated polyol 110 and the aliphatic isocyanate 120. In this example, each of the two mixtures can include a different solvent.

### 7. Manufacturing

The hybrid copolymer composition 100 can be manufactured via a continuous roll-to-roll process, described in further detail in U.S. patent application Ser. No. 15/895,971, that produces a thin layer exhibiting both chemical and physical cross-linking to yield clear optical properties and particular mechanical properties, such as resistance to impact, pencil hardness, etc.

The hybrid copolymer composition 100 can be manufactured via a roll-to-roll manufacturing process including: mixing a first solution and a second solution to define a viscous material, the first solution including a first proportion of a polyisocyanate-terminated polyol 110, a second proportion of an aliphatic polyisocyanate 120, and a seventh proportion of the solvent, the second solution including a third proportion of a curative 130, a fourth proportion of a soft polymer chain 140, a fifth proportion of a high functionality crosslinker 150, and a sixth proportion of a catalyst; advancing a substrate from a first roll across a surface continuously at a first speed; depositing the first viscous material characterized by a first viscosity through a deposition head onto the substrate, the first viscous material flowing laterally across the substrate to form a thin layer of substantially uniform thickness over the substrate over a period of time while the substrate advances along the surface; heating the thin layer to remove solvent from the thin layer and to induce reaction between the prepolymer, the aliphatic polyisocyanate, the curative, the soft polymer chain, and the cross-linking agent and to cure the thin layer via physically and chemically cross-linked polymer chains.

In one implementation, the hybrid copolymer composition 100 can be manufactured by mixing a first solution and a second solution before combining the first solution and the second solution. The first solution includes: twenty percent to eighty percent of the first proportion of aliphatic-diisocyanate-terminated polyol in and the second proportion of additional diisocyanates 121 by weight; and up to eighty percent of a first solvent by weight. The first solution can include between fifty percent to eighty percent of the total solid content of the hybrid copolymer composition 100 by weight while the second solution can include twenty to fifty percent of the total solid content of the hybrid copolymer composition 100 by weight. The second solution includes: twenty percent to eighty percent of the third proportion of an aromatic diamine curative 131, the fourth proportion of a polyester polyol 141, and the fifth proportion of a high functionality dendrimer 151; and up to eighty percent of a second solvent (which may be the same solvent as the first solvent or a different solvent). The hybrid copolymer composition 100 can then be manufactured by combining the first solution and the second solution via a roll-to-roll manufacturing process (e.g., as described above) at a ratio between one-to-one and four-to-one by weight. Additionally, the hybrid copolymer composition 100 can be manufactured by adding a sixth proportion of a catalyst (e.g., dibutyltin dilaurate) to the second solution before combining first solution and the second solution, the sixth proportion defining between zero percent and two percent of the hybrid copolymer composition 100 by weight. For example, a first proportion of H12MDI terminated PTMEG as the aliphatic-polyisocyanate-terminated polyol in and a mixture of H12MDI and TMXDI as the second proportion of additional diisocyanates 121 can be mixed to form a first solution. The H12 MDI forms a defined hard segment in the final hybrid copolymer composition 100, thus increasing the strength and high temperature storage modulus of the final hybrid copolymer composition 100, while the PTMEG improves the elastomeric properties of the hybrid copolymer composition 100. The TMXDI forms a hard segment, thus increasing the strength and rigidity of the hybrid copolymer composition 100, while preventing color changes (e.g., preventing the protective film layer 102 from turning yellow). Separately, diethyltoluene diamine as the aromatic diamine curative 131, polycaprolactone diol as the polyester polyol 141, and an alcohol dendrimer as the high functionality dendrimer 151 can be mixed to form a second solution. The diethyltoluene diamine forms a well-defined hard segment in the final hybrid copolymer composition 100, thus increasing strength of the hybrid copolymer composition 100 at both low temperatures and high temperatures. The polycaprolactone diol disrupts the soft segment (e.g., PTMEG chains) morphology and lowers the low temperature storage modulus, thus counteracting the increase in low temperature storage modulus caused by the inclusion of TMXDI and diethyltoluene diamine. The alcohol dendrimer, when reacted with other components, forms a highly crosslinked polymer exhibiting large distances between cross-links, which enables the hybrid copolymer composition 100 to remain relatively ductile at low temperatures and stable at high temperatures. The hybrid copolymer composition can be manufacture by mixing the first solution and the second solution via a roll-to-roll process, thus forming the hybrid copolymer composition 100. The synergistic effects of each of these components enables the hybrid copolymer composition 100 to exhibit increases in storage modulus at high temperatures and decreases in storage modulus at low temperatures, each independently of the other.

As a person skilled in the art will recognize from the previous detailed description and from the figures and claims, modifications and changes can be made to the embodiments of the invention without departing from the scope of this invention as defined in the following claims.

I claim:

1. A hybrid copolymer composition comprising:
a first proportion of an aliphatic-diisocyanate-terminated polyol;
a second proportion of additional diisocyanates;
a third proportion of an aromatic diamine curative configured to extend a chain length of the aliphatic-diisocyanate-terminated polyol and the additional diisocyanates;
a fourth proportion of a polyester polyol configured to polymerize with the aliphatic-diisocyanate-terminated polyol and the additional diisocyanates; and
a fifth proportion of a high functionality crosslinker configured to crosslink the aliphatic-diisocyanate-terminated polyol and the additional diisocyanates.

2. The hybrid copolymer composition of claim 1 configured to form a protective film layer in a foldable electronic display, the foldable electronic display comprising:
a cover layer arranged beneath the protective film layer; and
an array of organic light-emitting diodes arranged beneath the cover layer.

3. The hybrid copolymer composition of claim 1, configured to form a sponge film layer in a foldable electronic display, the foldable electronic display comprising:
a mechanical housing arranged over the sponge film layer; and
an array of organic light-emitting diodes arranged above the mechanical housing.

4. The hybrid copolymer composition of claim 1, configured to form a protective film layer in a foldable electronic display, the foldable electronic display comprising;
a cover layer arranged above the protective film layer; and
an array of organic light-emitting diodes arranged beneath the protective film layer.

5. The hybrid copolymer composition of claim 1, wherein the second proportion of additional diisocyanate comprises a quantity of aliphatic diisocyanate.

6. The hybrid copolymer composition of claim 1, wherein the second proportion of diisocyanate comprises a first quantity of an aliphatic diisocyanate and a second quantity of an aromatic diisocyanate.

7. The hybrid copolymer composition of claim 1 manufactured by:
mixing a first solution comprising:
twenty percent to eighty percent of the first proportion and the second proportion by weight; and
up to eighty percent of a first solvent by weight;
mixing a second solution comprising:
twenty percent to eighty percent of the third proportion, the fourth proportion, and the fifth proportion; and
up to eighty percent of a second solvent by weight; and
combining the first solution and the second solution via a roll-to-roll manufacturing process at a ratio between one-to-one and four-to-one.

8. The hybrid copolymer composition of claim 7:
further manufactured by mixing the second solution comprising up to two percent of a sixth proportion of a catalyst, the catalyst comprising dibutyltin dilaurate.

9. The hybrid copolymer composition of claim 1:
exhibiting a low temperature storage modulus between 400 MPa and 1400 MPa at −20 degrees Celsius;
exhibiting a high temperature storage modulus between 10 MPa and 100 MPa at 85 degrees Celsius; and
exhibiting a room temperature storage modulus between 100 MPa and 400 MPa at 20 degrees Celsius;
exhibiting an elongation at break greater than 400%.

10. The hybrid copolymer composition of claim 1:
wherein the first proportion, the second proportion, the third proportion, the fourth proportion, and the fifth proportion define a molar ratio of polyurethane segments to polyurea segments between two-to-five and six-to-five.

11. hybrid copolymer composition of claim 1:
exhibiting a bulk density between 1.1 and 1.4 g/cm₃; and
exhibiting a void fraction between three and twenty percent.

12. A hybrid copolymer composition comprising:
a molar ratio of a first number of polyurethane linkages to a second number of polyurea linkages between two-to-five and six-to-five;
the first number of polyurethane linkages:
connecting a first quantity of polyether polyol segments to a second quantity of aliphatic diisocyanate terminations;
connecting a third quantity of polyester polyol segments to the second quantity of the aliphatic diisocyanate terminations and a fourth quantity of additional diisocyanates; and
connecting a fifth quantity of a high functionality crosslinker to the second quantity of the aliphatic diisocyanate terminations and the fourth quantity of additional diisocyanates; and
the second number of polyurea linkages connecting a sixth quantity of an aromatic polyamine curative to the second quantity of the aliphatic diisocyanate terminations and the fourth quantity of additional diisocyanates.

13. The hybrid copolymer composition of claim 12:
exhibiting a low temperature storage modulus between 400 MPa and 1400 MPa at −20 degrees Celsius;
exhibiting a high temperature storage modulus between 10 MPa and 100 MPa at 85 degrees Celsius; and
exhibiting a room temperature storage modulus between 100 MPa and 400 MPa at 20 degrees Celsius;
exhibiting an elongation at break greater than 400%.

14. The hybrid copolymer composition of claim 12 wherein the first quantity of polyether polyol segments comprises poly(tetramethylene ether) glycol.

15. The hybrid copolymer composition of claim 12 wherein the third quantity of polyester polyol segments comprises polycaprolactone polyol diol.

16. The hybrid copolymer composition of claim 12 wherein the fifth quantity of high functionality crosslinker comprises an alcohol dendrimer characterized by a functionality greater than five.

17. The hybrid copolymer composition of claim 12 wherein the sixth quantity of an aromatic polyamine curative comprises diethyl toluene diamine.

18. A hybrid copolymer composition:
comprising:
a first proportion of a polyisocyanate-terminated polyol;
a second proportion of additional polyisocyanates;
a third proportion of a curative;
a fourth proportion of a soft polymer chain; and
a high functionality crosslinker;
exhibiting:
a first storage modulus between 400 MPa and 1400 MPa at −20 degrees Celsius;
a second storage modulus between 10 MPa and 100 MPa at 85 degrees Celsius; and
a room temperature storage modulus between 100 MPa and 400 MPa at 20 degrees Celsius; and
exhibiting an elongation at break greater than 400%.

19. The hybrid copolymer composition of claim 18, configured to form a film exhibiting no measurable permanent deformation after the film is folded around a 2-millimeter radius mandrel for a duration between two hours and six hours at a temperature between 20° C. and 25° C.

20. The hybrid copolymer composition of claim 18, configured to form a film exhibiting no measurable permanent deformation after the film is repeatedly folded and unfolded around a 2-millimeter radius mandrel at a frequency of 1 Hz for greater than 200,000 cycles.
